(19) United States
(12) Patent Application Publication
(10) Pub. No.: US 2026/0047408 A1
(43) Pub. Date: Feb. 12, 2026

(54) HIGH VOLTAGE SEMICONDUCTOR DEVICE ISOLATION STRUCTURE AND METHOD OF MANUFACTURING SAME

(71) Applicant: DB HiTek Co., Ltd., Bucheon-si (KR)

(72) Inventor: Jong Won SUN, Icheon-si (KR)

(21) Appl. No.: 18/916,917

(22) Filed: Oct. 16, 2024

(30) Foreign Application Priority Data
Aug. 6, 2024 (KR) 10-2024-0104304

(51) Int. Cl. H01L 21/762; H01L 29/06; H01L 21/265

(52) U.S. Cl. CPC H10W 10/014; H10D 62/10; H10W 10/0121; H10W 10/13; H10W 10/17; H10P 30/20

(57) ABSTRACT

A high voltage semiconductor device isolation structure and a method of manufacturing the same prevent a silicon penetration region from being formed between a first STI region and the side wall of a DTI region so that the breakdown voltage characteristic of a device is prevented from being decreased due to electric field concentration on the penetration region, and a method of manufacturing the same.

### CROSS REFERENCE TO RELATED APPLICATION

The present application claims priority to Korean Patent Application No. 10-2024-0104304, filed August 6, 2024, the entire contents of which are incorporated herein for all purposes by this reference.

### BACKGROUND OF THE INVENTION

### FIELD OF THE INVENTION

The present disclosure relates generally to a high voltage semiconductor device isolation structure and a method of manufacturing the same. More particularly, the present disclosure relates to a high voltage semiconductor device isolation structure which prevents a silicon penetration region from being formed between a first STI region and the side wall of a DTI region so that the breakdown voltage characteristic of a device is prevented from being decreased due to electric field concentration on the penetration region, and a method of manufacturing the same.

### DESCRIPTION OF THE RELATED ART

A BCDMOS (Bipolar-CMOS-DMOS) process requires a high breakdown voltage of 100V or more, and in accordance with this high voltage requirement, the process of forming a deep trench isolation (DTI) region is used to prevent an increase in leakage current through electrical isolation between adjacent devices.

FIG. 1 is a cross-sectional view illustrating a conventional semiconductor device isolation structure. Hereinafter, the conventional semiconductor device isolation structure and problems thereof will be described in detail with reference to FIG. 1.

Referring to FIG. 1, in a conventional semiconductor device, a buried layer 910 of a second conductivity type is formed at a predetermined depth within a substrate 901. In addition, a DTI region 921 and 923 is formed from the surface of the substrate 901 to a predetermined depth. The DTI region 921 and 923 may include a sidewall 921 and a polysilicon layer 923 that fills a deep trench on the sidewall 921.

In addition, the STI region 930 may be formed inside the substrate 901 and at the outer wall of the sidewall 921 of the DTI region. The STI region 930 may generally be formed after the DTI regions 921 and 923 are formed. In this case, it is preferable that the STI region 930 and the DTI regions 921 and 923 are in complete contact with each other without being spaced apart from each other.

However, when the STI region 930 is formed after the DTI regions 921 and 923 are formed as described above, a conical silicon penetration region CS with a crack shape may be formed between the STI region 930 and the outer wall of the sidewall 921. When the penetration region CS is formed, this may a factor in reducing the breakdown voltage characteristics of the device due to electric field concentration on the penetration region CS when a high voltage is applied to the device.

In addition, when using the structure of the DTI region 921 and 923 described above, as the operating voltage of the device increases, an electric field is concentrated on a point at which the buried layer 910 and the DTI regions 921 and 923 meet each other and on the upper portion of the DTI regions 921 and 923, which may be another factor in lowering the breakdown voltage characteristics of the device.

In order to solve this problem, the inventors of the present invention are intended to propose a new high voltage semiconductor device isolation structure with an improved structure and a method of manufacturing the same, and details thereof will be described later.

### Document of Related Art

(Patent Document) Korean Patent Application Publication No. 10-2003-0000592 'METHOD FOR MANUFACTURING SEMICONDUCTOR DEVICE WITH STI/DTI STRUCTURE

### SUMMARY OF THE INVENTION

Accordingly, the present disclosure has been made keeping in mind the above problems occurring in the related art, and the present disclosure is intended to propose a high voltage semiconductor device isolation structure which prevents the formation of a silicon penetration region or minimizes the silicon penetration region between a first STI region and an outer wall of a DTI region so that the breakdown voltage characteristic of a device is prevented from being decreased due to electric field concentration on the penetration region, and a method of manufacturing the same .

In addition, the present disclosure is intended to propose a high voltage semiconductor device isolation structure, in which the silicon penetration region is removed by changing only a mask pattern during a LOCOS process so as not to require an additional process for removing the penetration region so that a decrease in process efficiency is prevented, and a method of manufacturing the same.

In addition, the present disclosure is intended to propose a high voltage semiconductor device isolation structure, in which the vertical thickness and/or width of a first STI region is increased by a thermal oxidation process to improve the breakdown voltage characteristics of the device, and a method of manufacturing the same.

In addition, the present disclosure is intended to propose a high voltage semiconductor device isolation structure, in which an ion implantation region is formed under a buried layer within a substrate in which the DTI region is formed to mitigate electric field concentration on a point on which the buried layer and the DTI region are in contact with each other or adjacent to each other, thereby enhancing isolation characteristics, and a method of manufacturing the same.

In addition, the present disclosure is intended to propose a high voltage semiconductor device isolation structure, in which the ion implantation region is pre-formed in the substrate before the buried layer is formed so that the ion implantation region is easily formed at a desired depth in the substrate, and a method of manufacturing the same.

In addition, the present disclosure is intended to propose a high voltage semiconductor device isolation structure, in which a gap-fill region is formed through the substrate under a deep trench by epitaxial growth, thereby enabling an easy gap-fill process within the deep trench, and a method of manufacturing the same.

The present disclosure may be implemented through embodiments with the following configuration to achieve the purposes described above.

According to an embodiment of the present disclosure, a high voltage semiconductor device isolation structure of the present disclosure includes: a substrate: a DTI region extending to a predetermined depth from a surface of the substrate; and an STI region extending to a predetermined depth from the surface of the substrate, wherein the STI region includes: a first STI region that is in contact with or overlaps an outer wall of the DTI region; and a second STI region that is spaced apart from the first STI region and the DTI region.

According to another embodiment of the present disclosure, in the high voltage semiconductor device isolation structure of the present disclosure, the first STI region may have a size different from a size of the second STI region.

According to another embodiment of the present disclosure, in the high voltage semiconductor device isolation structure of the present disclosure, the first STI region may have a width larger than a width of the second STI region.

According to another embodiment of the present disclosure, in the high voltage semiconductor device isolation structure of the present disclosure, the first STI region may include an outer region having one side in entire contact with the outer wall of the DTI region.

According to another embodiment of the present disclosure, in the high voltage semiconductor device isolation structure of the present disclosure, a lower surface of an outer region may be located at a side deeper within the substrate than a lower surface of the second STI region.

According to another embodiment of the present disclosure, the high voltage semiconductor device isolation structure of the present disclosure may further include: a field oxide film on the surface of the substrate, wherein the first STI region may grow through a thermal oxidation process during a formation process of the field oxide film.

According to another embodiment of the present disclosure, in the high voltage semiconductor device isolation structure of the present disclosure, the first STI region may include an inner region that overlaps the DTI region.

According to another embodiment of the present disclosure, in the high voltage semiconductor device isolation structure of the present disclosure, the inner region may have a structure in which a lower surface of the inner region is convex downward.

According to another embodiment of the present disclosure, a high voltage semiconductor device isolation structure of the present disclosure includes: a substrate: a DTI region extending to a predetermined depth from a surface of the substrate; an STI region extending to a predetermined depth from the surface of the substrate and having a smaller vertical length compared to the DTI region; and a field oxide film on the surface of the substrate, wherein the STI region includes: a first STI region that is in contact with or overlaps an outer wall of the DTI region; and a second STI region that is spaced apart from the first STI region and the DTI region, wherein the first STI region includes: an outer region having one side in entire contact with the outer wall of the DTI region; and an inner region that overlaps the DTI region.

According to another embodiment of the present disclosure, in the high voltage semiconductor device isolation structure of the present disclosure, the STI region may be formed after the DTI region is formed.

According to another embodiment of the present disclosure, in the high voltage semiconductor device isolation structure of the present disclosure, a lower surface of the outer region may be located at a side deeper within the substrate than a lower surface of the second STI region.

According to another embodiment of the present disclosure, in the high voltage semiconductor device isolation structure of the present disclosure, the first STI region may have a lower part connected directly to the outer wall of the DTI region adjacent thereto.

According to another embodiment of the present disclosure, in the high voltage semiconductor device isolation structure of the present disclosure, the first STI region may be completed by performing a LOCOS process.

According to another embodiment of the present disclosure, in the high voltage semiconductor device isolation structure of the present disclosure, the inner region may have a lower surface that is not substantially flat.

According to an embodiment of the present disclosure, a method of manufacturing a high voltage semiconductor device isolation structure of the present disclosure includes: forming a deep trench by etching a substrate; forming a DTI region within the deep trench; forming, within the substrate, a first STI region that is in contact with or overlaps an outer wall of the DTI region, and a second STI region that is spaced apart from the DTI region and the first STI region; and forming a field oxide film on a surface of the substrate, wherein the first STI region is grown by a thermal oxidation process performed during the forming of the field oxide film.

According to another embodiment of the present disclosure, in the method of manufacturing the high voltage semiconductor device isolation structure of the present disclosure, the forming of the field oxide film may include: forming a pad oxide film on the substrate; forming a nitride film on the pad oxide film; removing, partially, the nitride film by forming a photoresist film on the nitride film; and forming the field oxide film and growing the first STI region by growing the pad oxide film by the thermal oxidation process.

According to another embodiment of the present disclosure, in the method of manufacturing the high voltage semiconductor device isolation structure of the present disclosure, the first STI region may include: an outer region having one side in entire contact with the outer wall of the DTI region; wherein a lower surface of the outer region may be located at a side deeper within the substrate than a lower surface of the second STI region.

According to another embodiment of the present disclosure, in the method of manufacturing the high voltage semiconductor device isolation structure of the present disclosure, the outer region may have one lateral lowest end portion in direct contact with the outer wall of the DTI region adjacent thereto.

According to another embodiment of the present disclosure, in the method of manufacturing the high voltage semiconductor device isolation structure of the present disclosure, the first STI region may further include: an inner region that overlaps the DTI region, wherein the inner region may have a curved cross-sectional shape at an edge of a lower surface thereof.

According to another embodiment of the present disclosure, the method of manufacturing the high voltage semiconductor device isolation structure of the present disclosure may further include: forming an ion implantation region within the substrate before forming the DTI region; and forming a buried layer on the ion implantation region before forming the DTI region.

The present disclosure has the following effects due to the configuration described above.

According to the present disclosure, the silicon penetration region is not formed or minimized between the first STI region and the outer wall of the DTI region, thereby preventing the deterioration of the breakdown voltage characteristics of the device due to electric field concentration on the penetration region.

In addition, according to the present disclosure, the silicon penetration region is removed by changing only the mask pattern during the LOCOS process so as not to require an additional process to remove the penetration region, thereby preventing a decrease in process efficiency.

In addition, according to the present disclosure, the vertical thickness and/or width of the first STI region is increased by a thermal oxidation process, thereby resulting in an improvement in the breakdown voltage characteristics of the device.

In addition, according to the present disclosure, the ion implantation region is formed under the buried layer within the substrate in which the DTI region is formed to mitigate electric field concentration on a point on which the buried layer and the DTI region are in contact with each other or adjacent to each other, thereby enhancing isolation characteristics.

In addition, according to the present disclosure, the ion implantation region is pre-formed in the substrate before the buried layer is formed, thereby allowing the ion implantation region to be easily formed at a desired depth in the substrate.

In addition, according to the present disclosure, a gap-fill region is formed through a side of the substrate under the deep trench by epitaxial growth, thereby enabling an easy gap-fill process within the deep trench.

Meanwhile, it should be added that even if effects are not explicitly mentioned here, the effects described in the following specifications and potential effects thereof expected by the technical features of the present disclosure are treated as if they were described in the specifications of the present disclosure.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view illustrating a conventional semiconductor device isolation structure;

FIG. 2 is a cross-sectional view illustrating a high voltage semiconductor device isolation structure according to an embodiment of the present disclosure;

FIG. 3 is an enlarged view illustrating the structures of a first STI region and a second STI region according to FIG. 2; and

FIGS. 4 to 21 are cross-sectional views illustrating a method of manufacturing the high voltage semiconductor device isolation structure according to an embodiment of the present disclosure.

### DETAILED DESCRIPTION OF THE INVENTION

Hereinafter, embodiments of the present disclosure will be described in more detail with reference to the attached drawings. The embodiments of the present disclosure may be modified in various forms, and the scope of the present disclosure should not be construed as limited to the embodiments below and should be interpreted on the basis of the matters stated in the claims. In addition, these embodiments are only provided as a reference to more completely explain the present disclosure to those with average knowledge in the art.

Hereinafter, when a first component (or layer) is described as being placed on a second component (or layer), it should be noted that the first component may be placed directly on the second component, or there may be a third component(s) or layer(s) located between the corresponding components. Additionally, when the first component is expressed as being placed directly on or above the second component, no other component(s) are located between the corresponding components. In addition, being located on the 'upper part', 'lower part', 'upper side', 'lower side' or 'one side' or 'side surface' of the first component means a relative positional relationship.

Additionally, terms such as first and second, etc. may be used to describe various items such as various elements, regions, and/or parts, but the items are not limited by these terms.

In addition, it should be noted that in a case in which a specific embodiment can be implemented differently, a specific process sequence may be different from a process sequence to be described below. For example, two processes described sequentially may be performed substantially at the same time or may be performed in the opposite order.

A metal-oxide semiconductor (MOS), which is a term used below, is a general term, and 'M' is not limited just to metal and may be composed of various types of conductors. In addition, 'S' may be a substrate or a semiconductor structure, and 'O' is not limited to oxides and may include various types of organic or inorganic materials.

Additionally, the conductivity type or doped regions of components may be defined as 'P-type' or 'N-type' according to characteristics of a main carrier. However, this is merely for convenience of explanation and the technical spirit of the present disclosure is not limited to examples provided. For example, hereinafter, more general terms 'first conductivity type' or 'second conductivity type' will be used as 'P-type' or 'N-type', in which the first conductivity type refers to P-type and the second conductivity type refers to N-type.

Additionally, terms 'high concentration' and 'low concentration', which express the doping concentration of impurity regions should be understood to mean relative doping concentrations between one component and another component.

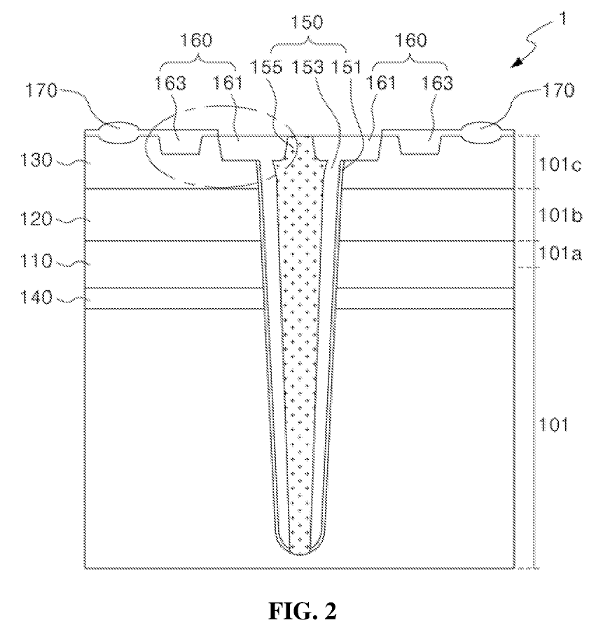

FIG. 2 is a cross-sectional view illustrating a high voltage semiconductor device isolation structure according to an embodiment of the present disclosure.

Hereinafter, a high voltage semiconductor device isolation structure 1 according to an embodiment of the present disclosure will be described in detail with reference to the accompanying drawings.

Referring to FIG. 2, the present disclosure relates to the high voltage semiconductor device isolation structure 1 and, more particularly, to the high voltage semiconductor device isolation structure 1 which prevents a silicon penetration region from being formed between a first STI region and a side wall of a DTI region so that the breakdown voltage characteristic of a device is prevented from being degraded due to electric field concentration on the penetration region.

It is preferable that the formation depth of a DTI region 150 described below is approximately 30µm or more and 40µm or less from the surface of a substrate 101, but it should be noted that the scope of the high voltage semiconductor device isolation structure of the present disclosure is not limited by the numerical range.

The high voltage semiconductor device isolation structure 1 according to an embodiment of the present disclosure may first include the substrate 101. A well region utilized as an active region may be formed in the substrate 101, and this active region may be defined by an STI region 160, which will be described later, as a device isolation film. In addition, the substrate 101 may be a substrate doped with a first conductivity type, may be a P-type diffusion region disposed within the substrate, or may include a P-type epitaxial layer epitaxially grown on the substrate. Preferably, a first epitaxial layer 101a, a second epitaxial layer 101b, and a third epitaxial layer 101c may be sequentially formed in the substrate 101, but the scope of the present disclosure is not limited thereto. Hereinafter, except a case in which the substrate 101 and the epitaxial layers 101ato 101c are clearly distinguished, when referring to the substrate 101, it is understood to include one or more epitaxial layers on the substrate.

In addition, a buried layer 110 may be formed in the substrate 101. For example, the buried layer 110, which is the high-concentration doped region of a second conductivity-type impurity, may be formed at a predetermined depth in the substrate 101. Preferably, the buried layer 110 may be formed in the substrate 101 and in the first epitaxial layer 101a in the substrate 101. Additionally, the buried layer 110 may be in contact with the outer wall of the DTI region 150 adjacent thereto or may be formed on a side adjacent to the DTI region 150, but there is no separate limitation thereon.

In addition, a high-voltage well region 120 may be formed within the substrate 101. For example, the high-voltage well region 120, which is a second conductivity-type impurity doped region, may be formed on the buried layer 110 within the substrate 101. Preferably, the high-voltage well region 120 may be formed within the second epitaxial layer 101b in the substrate 101. In addition, the high-voltage well region 120 may have a side connected to the buried layer 110. It should be noted that the described high-voltage well region 120 is not an essential element of the present disclosure and may be omitted in some cases.

In addition, a deep well region 130 may be formed on the high voltage well region 120 in the substrate 101. The deep well region 130 may have one side connected to the high voltage well region 120 or the buried layer 110 and, for example, may be a second conductivity-type impurity doped region. Preferably, the deep well region 130 may be formed within the third epitaxial layer 101c in the substrate 101. In addition, a drain region (not shown) may be formed within the deep well region 130. The high voltage well region 120 and the deep well region 130 which are described above may be in contact with the outer wall of the adjacent DTI region 150 or may be formed on a side adjacent to the DTI region 150, but there is no separate limitation thereon.

In addition, an ion implantation region 140 may be formed under the buried layer 110 within the substrate 101. The ion implantation region 140, for example, may have an upper surface formed to be in contact with the lower surface of the buried layer 110, and may be a second conductivity-type impurity doped region. In addition, the ion implantation region 140, for example, is preferably a low-concentration doped region of a second conductivity-type impurity compared to the buried layer 110, the high voltage well region 120, and the deep well region 130. In addition, the ion implantation region 140 is preferably formed before the buried layer 110 is formed within the substrate 101. Accordingly, by forming the ion implantation region 140 within the substrate 101, electric field concentration on a point on which the buried layer 110 and the DTI region 150 are in contact with each other or are adjacent to each other may be mitigated, thereby improving the breakdown voltage characteristics of a semiconductor device. In addition, the ion implantation region 140 is preferably formed in the substrate 101 under the first epitaxial layer 101a. For example, the ion implantation region 140 may be formed at a predetermined depth spaced apart from the surface of the substrate 101. The detailed description of the formation of the ion implantation region 140 will be described later.

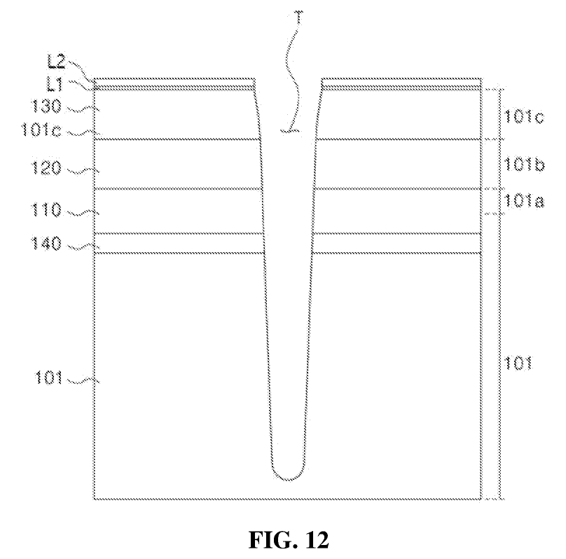

In addition, the DTI region 150 may be formed within the substrate 101. The DTI region 150 is, for example, a region extending from the upper surface of the third epitaxial layer 101c to a predetermined depth within the substrate 101, and the side wall of the DTI region 150 may extend in a vertical direction or may be formed to be inclined to be narrower gradually downward. The DTI region 150 may include a liner 151. The liner 151 may be formed on the side wall of the DTI region 150 and may, for example, include an insulating material such as an oxide film. In addition, the DTI region 150 may further include a sidewall 153. The sidewall 153 is formed on the liner 151 within a deep trench T (see FIG. 12) and may include, for example, an oxide film. In addition, the DTI region 150 may further include a gap-fill region 155.

The gap-fill region 155, which is a region that gap-fills the deep trench T on the sidewall 153, preferably includes an electrically conductive material and, for example, more preferably includes polysilicon. In addition, the gap-fill region 155 may have a lower surface whose side is in contact with the substrate 101 at the lower side thereof. That is, the lower surface of the DTI region 150 is preferably formed to have a side that is not blocked by the liner 151 and the sidewall 153 so that the gap-fill region 155 is in direct contact with the substrate 101, but the scope of the present disclosure is not limited thereto. In addition, it is more preferable that the gap-fill region 155 is doped with a first conductivity type impurity and used as an electrode.

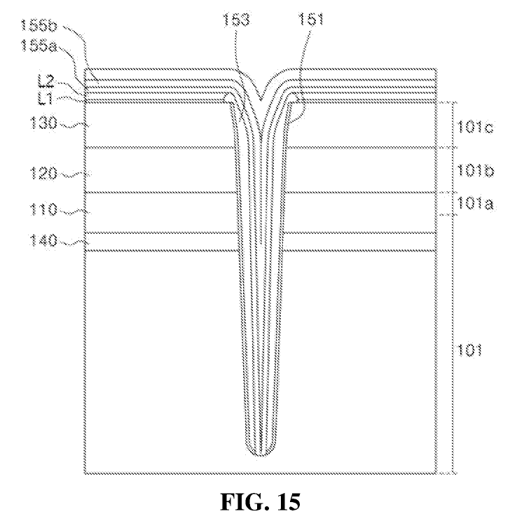

Below, the method of forming the gap-fill region 155 within the DTI region 150 will be described in detail. According to a first embodiment (see FIG. 15), multiple gap-fill material layers 155a and 155b are formed within the deep trench T in which the sidewall 153 is formed. That is, a first material layer 155a is formed within the deep trench T in which the sidewall 153 is formed, the first conductivity-type impurity is ion-implanted into the first material layer 155a, a second material layer 155b is formed on the first material layer 155a, and the first conductivity-type impurity is ion-implanted into the second material layer 155b. Next, by performing a heat treatment process, the gap-fill region 155 doped with the first conductivity-type impurities may be formed in the DTI region 150. In this case, the individual material layers 155a and 155b may include polysilicon or amorphous silicon (Si). In addition, two or more individual material layers may be formed, and there is no separate limit on the number thereof.

According to a second embodiment (see FIG. 15), the first material layer 155a doped with the first conductivity-type impurity may be gap-filled within the deep trench T in which the sidewall 153 is formed, the second material layer 155b doped with the first conductivity-type impurity may be formed on the first material layer 155a, and then heat treatment process may be performed to form the gap-fill region 155. In this case, the individual material layers 155a and 155b may include polysilicon or amorphous silicon (Si). In addition, two or more individual material layers may be formed, and there is no separate limit on the number thereof.

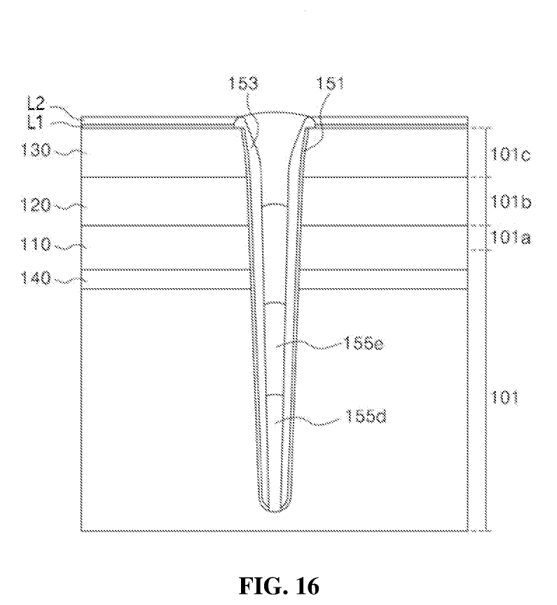

According to a third embodiment (see FIG. 16), one or more epitaxial growth regions are formed through a portion of the substrate 101 under the deep trench T in which the sidewall 153 is formed, and the first conductivity-type impurity is ion-implanted into individual epitaxial growth regions. Afterwards, the gap-fill region 155 may be formed by performing a heat treatment process. For example, after forming a first epitaxial growth region 155d on the lowest part of the deep trench T, the first conductivity-type impurity is ion-implanted into the first epitaxial growth region 155d. Afterwards, a second epitaxial growth region 155e is formed on the first epitaxial growth region 155d, and the first conductivity-type impurity is ion-implanted into the second epitaxial growth region 155e. The gap-fill region 155 may be formed by repeating the above process to gap-fill all of the deep trench T and performing a heat treatment process. In this case, there is no separate limitation on the number of epitaxial growth regions.

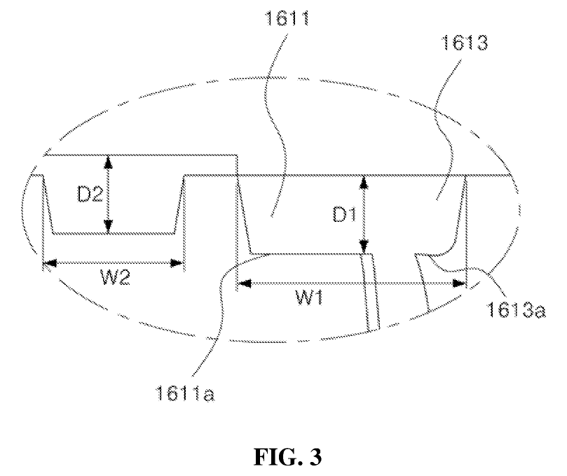

FIG. 3 is an enlarged view illustrating the structures of a first STI region and a second STI region according to FIG. 2.

Referring to FIG. 2 and FIG. 3, the STI region 160 may be formed within the substrate 101, and it is preferable that the STI region 160 is formed to a predetermined depth from the surface of the substrate 101. The STI region 160 may include a first STI region 161 and a second STI region 163.

The first STI region 161 may be formed to be in contact with the outer wall of the DTI region 150. In addition, the first STI region 161 may be formed to overlap the DTI region 150 within the substrate 101. More specifically, the first STI region 161 may have an outer region 1611 that is in contact with the outer wall of the DTI region 150 adjacent thereto, and an inner region 1613 that overlaps the DTI region 150. Below, the outer region 1611 and the inner region 1613 are described to be distinguishable, but this is for convenience of explanation, and it is preferable that the regions 1611 and 1613 are configured integrally to be directly connected to each other.

Referring to FIG. 3, the first STI region 161 is formed by performing the same process as the second STI region 163, and through a thermal oxidation process performed during the process of forming a field oxide film 170, an oxide film on the lower portion 1611a of the outer region 1611 may be grown and completed. In addition, by adjusting a mask pattern used in a LOCOS process, the oxide film of the inner region 1613 may also be grown. For example, when performing a LOCOS process on the entirety of the first STI region 161, the edge of the lower surface 1613a of the inner region 1613 may have a curved cross-sectional shape, or the lower surface 1613a may have a structure that is convex downward. For example, the edge of the lower surface 1613a of the inner region 1613 may have a downward convex structure. It should be noted that the LOCOS process for the inner region 1613 is not a required component of the present disclosure.

In addition, the horizontal width W1 of the first STI region 161 having the inner region 1613 may be larger than the horizontal width W2 of the second STI region 163 (W1 > W2). In addition, the vertical thickness D1 between the upper end of the outer region 1611 and the lowest end of the outer region 1611 may be larger than the vertical thickness D2 of the second STI region 163 (D1 > D2). Alternatively, the lower end of the outer region 1611 may be located at a side deeper within the substrate 101 than the lower end of the second STI region 163. Accordingly, the first STI region 161 and the second STI region 163 may have different shapes and/or sizes.

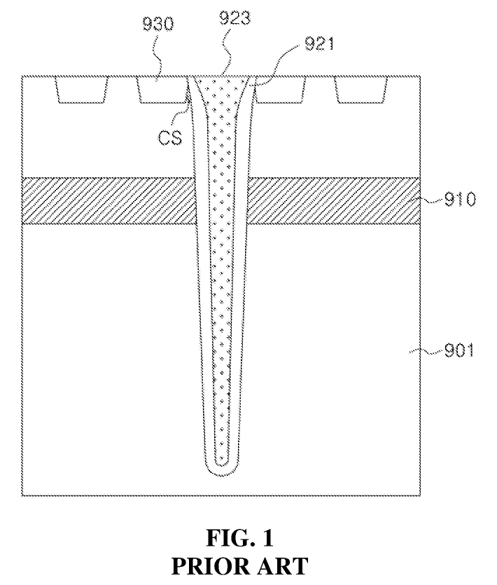

Generally, when the first STI region 161 is formed after the DTI region 150 is formed, a silicon penetration region CS (see FIG. 1) is formed between the outer wall of the DTI region 150 and the outer region 1611. To describe in more detail, a conical silicon penetration region CS with a crack shape is formed on a side at which the outer wall of the DTI region 150 and the outer region 1611 meet. The silicon penetration region CS may be a factor that reduces the breakdown voltage characteristics of the device due to electric field concentration when a high bias voltage is applied.

In an embodiment of the present disclosure, after forming the first STI region 161 through an STI process, the oxide film of the first STI region 161 grows at least partially through the LOCOS process, thereby removing or minimizing the silicon penetration region CS between the first STI region 161 and the DTI region 150.

In addition, the inner region 1613 is a configured to extend downward by a predetermined depth from the side portion of the upper surface of the DTI region 150. The inner region 1613 may be formed by adjusting only a mask pattern when forming the outer region 1611. As described above, an electric field is concentrated on the upper portion of the DTI region 150, which may deteriorate the breakdown voltage characteristics of the device. Accordingly, to prevent this, the first STI region 161 may be formed to have a side that overlaps the DTI region 150, such as the inner region 1613. However, it should be noted that the inner region 1613 is not a required component of the present disclosure.

Referring to FIG. 2, the second STI region 163 is configured to be formed from the surface of the substrate 101 to a predetermined depth, and may be completed before the formation process of the field oxide film 170, unlike the first STI region 161. Accordingly, the second STI region 163 is not affected by the formation process of the field oxide film 170, so the second STI region 163 may have a smaller vertical thickness than the outer region 1611 (D1 > D2), or the lowest end of the outer region 1611 may be located at a side deeper within the substrate 101 than the lowest end of the second STI region 163.

The field oxide film 170 is formed, for example, on the lower side of a gate electrode (not shown) to prevent electric field concentration on the edge of the gate electrode. The field oxide film 170 may be formed, for example, through the local oxidation of silicon (LOCOS) process. When performing the LOCOS process, the first STI region 161 may also be grown through a thermal oxidation process.

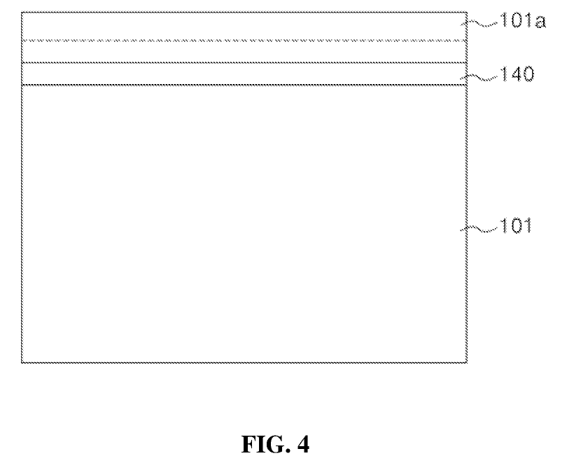

FIGS. 4 to 21 are cross-sectional views illustrating a method of manufacturing the high voltage semiconductor device isolation structure according to an embodiment of the present disclosure.

Hereinafter, the method of manufacturing the high voltage semiconductor device isolation structure according to an embodiment of the present disclosure will be described in detail with reference to the attached drawings.

Referring to FIG. 4, first, the ion implantation region 140 may be formed within the substrate 101. The ion implantation region 140 may be formed, for example, by ion-implantation of a second conductivity-type impurity into the substrate 101. The ion implantation region 140 may be formed on the surface of the substrate 101 or may be formed at a predetermined depth within the substrate 101. Next, the first epitaxial layer 101a is formed in the substrate 101 in which the ion implantation region 140 is formed.

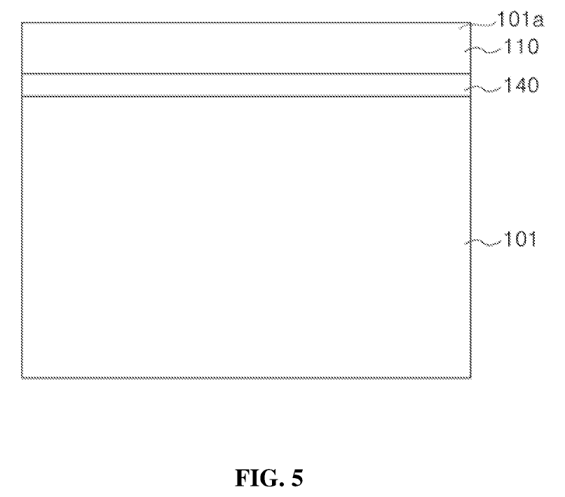

Next, referring to FIG. 5, the buried layer 110 is formed in the first epitaxial layer 101a. The buried layer 110, which is a second conductivity-type impurity doped region, is preferably a high-concentration doped region of a second conductivity-type impurity compared to the ion implantation region 140 described above. In addition, the buried layer 110 is located on the ion implantation region 140. As described, according to an embodiment of the present disclosure, it may be seen that after forming the ion implantation region 140 within the substrate 101, the first epitaxial layer 101a is formed and the buried layer 110 is formed within the first epitaxial layer 101a.

Unlike this, when the buried layer 110 is formed within the substrate 101, and the ion implantation region 140 is formed in the substrate 101 under the buried layer 110, due to high ion implantation energy required during the formation of the ion implantation region 140, it is inevitable that it is difficult to form the ion implantation region 140 at a desired depth within the substrate 101.

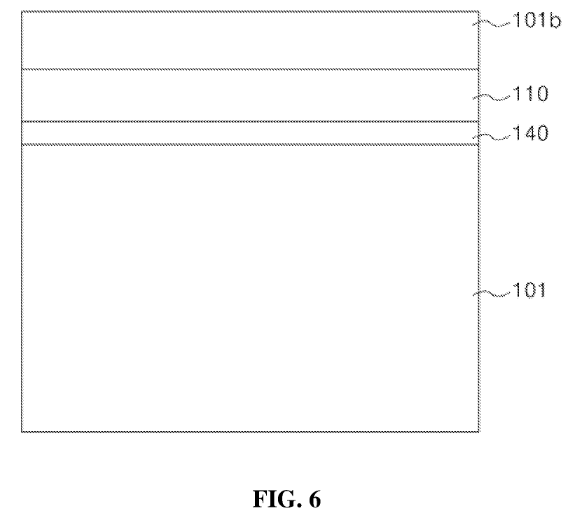

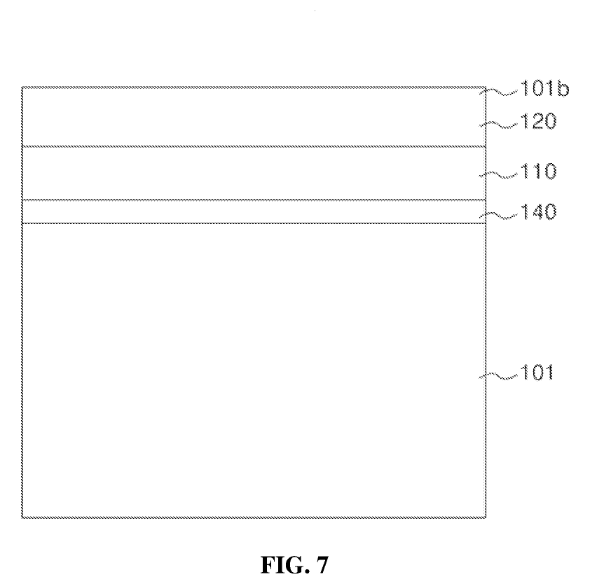

Referring to FIG. 6, after forming the buried layer 110, the second epitaxial layer 101b is formed on the first epitaxial layer 101a. In addition, referring to FIG. 7, the high voltage well region 120 may be formed within the second epitaxial layer 101b. The high voltage well region 120 is, for example, a second conductivity-type impurity doped region, and may be formed by the ion implantation of a second conductivity-type impurity into the second epitaxial layer 101b. However, as described above, the high voltage well region 120 is not an essential component of the present disclosure, and when the high voltage well region 120 is not formed, the third epitaxial layer 101c to be described later may be directly formed on the first epitaxial layer 101a.

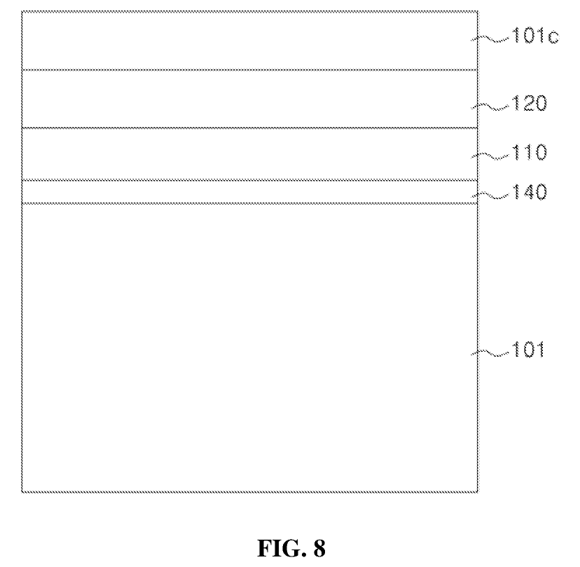

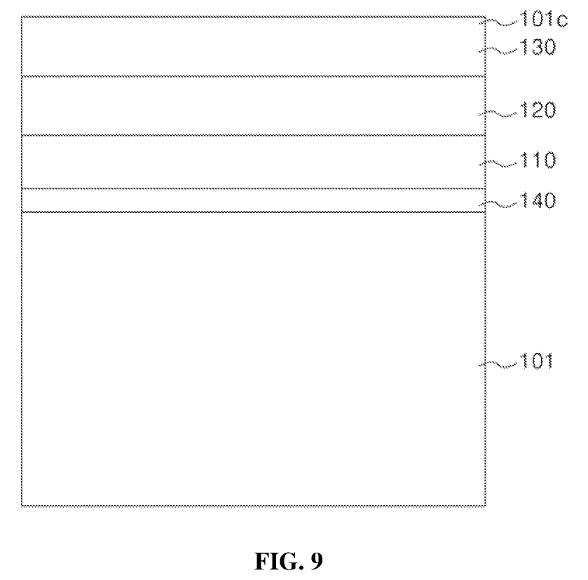

Referring to FIG. 8, after forming the high voltage well region 120, the third epitaxial layer 101c is formed on the second epitaxial layer 101b. In addition, referring to FIG. 9, the deep well region 130 may be formed in the third epitaxial layer 101c. The deep well region 130 is, for example, a second conductivity-type impurity doped region, and may be formed by the ion implantation of a second conductivity-type impurity into the third epitaxial layer 101c.

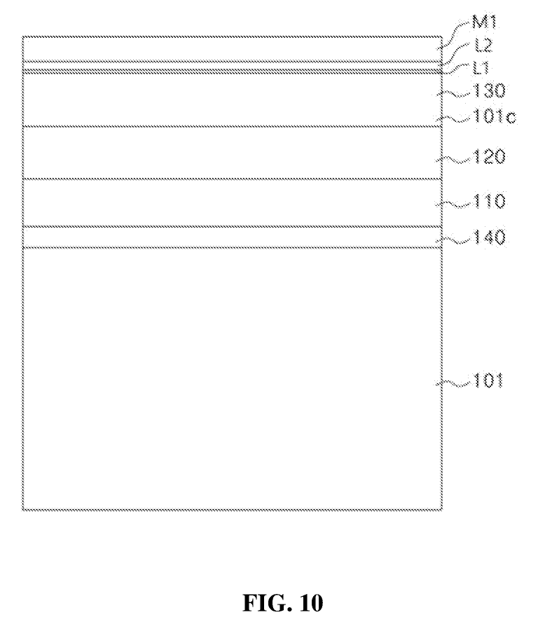

Next, referring to FIG. 10, a multilayer film may be formed on the third epitaxial layer 101c. To illustrate the process of forming the multilayer film, an oxide film L1 may be formed on the third epitaxial layer 101c, an etch stop film L2 may be formed on the oxide film L1, and a hard mask M1 may be formed on the etch stop film L2. The etch stop film L2 is an etch stop film in an etch-back process and a CMP process to be described later, and may include, for example, a nitride film. Additionally, the hard mask M1 may include, for example, an oxide film and a TEOS film formed by using low pressure chemical vapor deposition (LPCVD), but the present disclosure is not limited thereto.

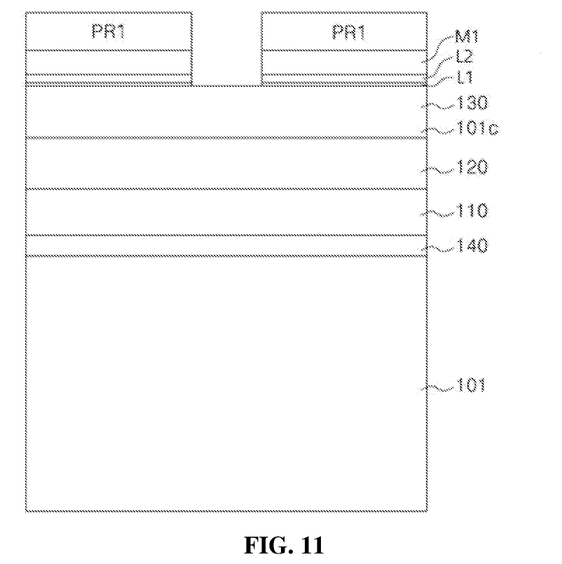

Next, referring to FIG. 11, a part of the multilayer film on a side on which the DTI region 150 will be formed is etched. For example, a photoresist film PR1 may be formed on the hard mask M1, and the open side of the photoresist film PR1 may be etched, and thus the hard mask M1, the etch stop film L2, and the oxide film L1 may be sequentially etched.

Next, referring to FIG. 12, each of the third epitaxial layer 101c, the second epitaxial layer 101b, the first epitaxial layer 101a, and the substrate 101 at the open side is etched to form the deep trench T. In this case, the deep trench T may be formed to a depth of approximately 30 µm or more and 40 µm or less from the surface of the third epitaxial layer 101c. In this process, the hard mask M1 may be removed together or at least partially removed. Afterwards, the photoresist film PR1 is removed.

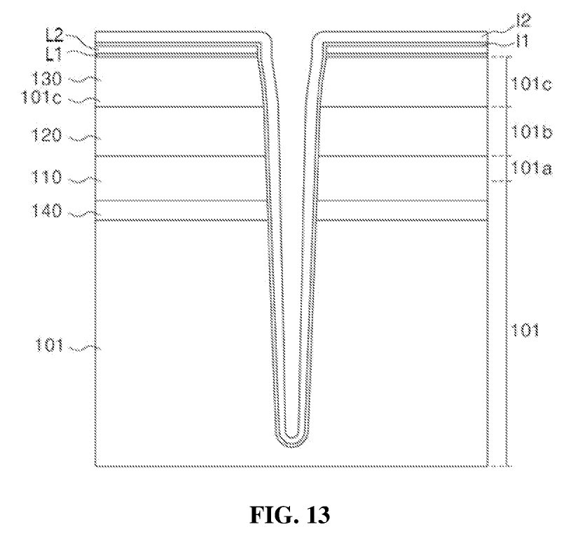

Next, referring to FIG. 13, a first insulating film I1 may be formed on the inner wall and lower surface of the deep trench T, and a second insulating film 12 may be formed on the first insulating film I1. In this case, the first insulating film I1 and the second insulating film 12 may be deposited even on the third epitaxial layer 101c.

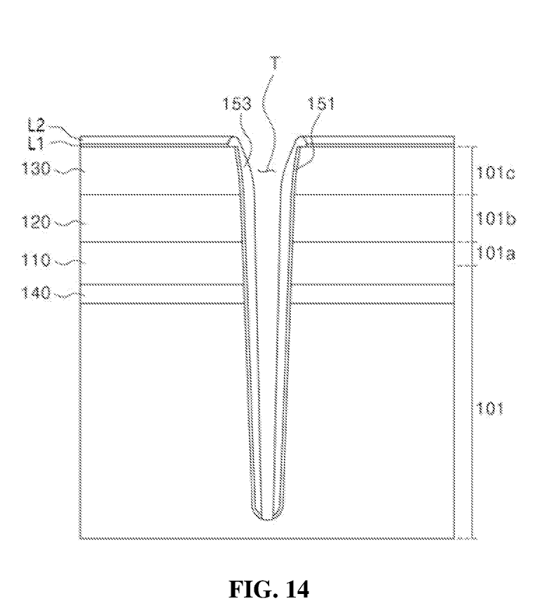

In addition, referring to FIG. 14, by performing an etch-back process on the first insulating film I1 and the second insulating film 12, the liner 151 and the sidewall 153 may be formed. As described above, a side of each of the first insulating film I1 and the second insulating film 12 located on the lower surface of the deep trench T may also be removed. That is, the lower surface of the deep trench T may have a portion that is not covered by the liner 151 and the sidewall 153.

Next, the gap-fill region 155 is formed on the sidewall 153 within the deep trench T.

According to the first embodiment (see FIG. 15), the multiple gap-fill material layers 155a and 155b are formed within the deep trench T in which the sidewall 153 is formed. That is, the first material layer 155a is formed within the deep trench T in which the sidewall 153 is formed, the first conductivity-type impurity is ion-implanted into the first material layer 155a, the second material layer 155b is formed on the first material layer 155a, and the first conductivity-type impurity is ion-implanted into the second material layer 155b. After that, by performing a heat treatment process, the gap-fill region 155 doped with the first conductivity-type impurities may be formed in the DTI region 150. In this case, the individual material layers 155a and 155b may include polysilicon or amorphous silicon (Si). In addition, two or more individual material layers may be formed, and there is no separate limit on the number thereof.

According to the second embodiment (see FIG. 15), the first material layer 155a doped with the first conductivity-type impurity may be gap-filled within the deep trench T in which the sidewall 153 is formed, the second material layer 155b doped with the first conductivity-type impurity may be formed on the first material layer 155a, and then a heat treatment process may be performed to form the gap-fill region 155. In this case, the individual material layers 155a and 155b may include polysilicon or amorphous silicon (Si). In addition, two or more individual material layers may be formed, and there is no separate limit on the number thereof.

According to the third embodiment (see FIG. 16), one or more epitaxial growth regions are formed through a portion of the substrate 101 under the deep trench T in which the sidewall 153 is formed, and the first conductivity-type impurity is ion-implanted into the individual epitaxial growth regions. Next, by performing a heat treatment process, the gap-fill region 155 may be formed. For example, after forming the first epitaxial growth region 155d on the lowest part of the deep trench T, the first conductivity-type impurity is ion-implanted into the first epitaxial growth region 155d. Next, the second epitaxial growth region 155e is formed on the first epitaxial growth region 155d, and the first conductivity-type impurity is ion-implanted into the second epitaxial growth region 155e. The gap-fill region 155 may be formed by repeating the above process to gap-fill all of the deep trench T and performing a heat treatment process. In this case, there is no separate limitation on the number of the epitaxial growth regions.

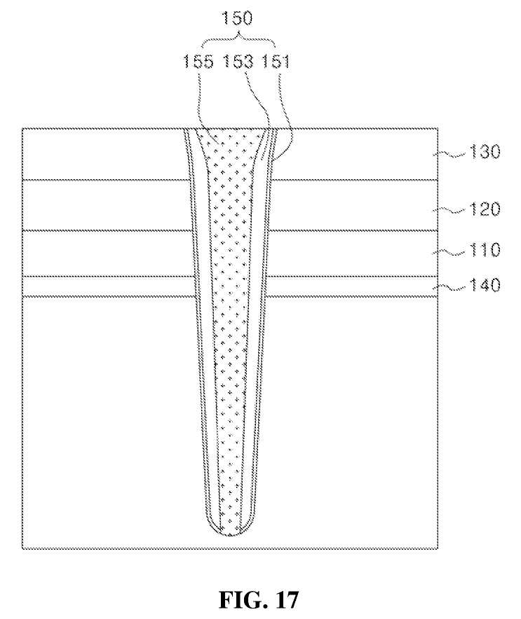

Next, referring to FIG. 17, by performing a CMP process, the upper side of the gap-fill region 155 may be planarized. Next, the etch stop film L2 is removed.

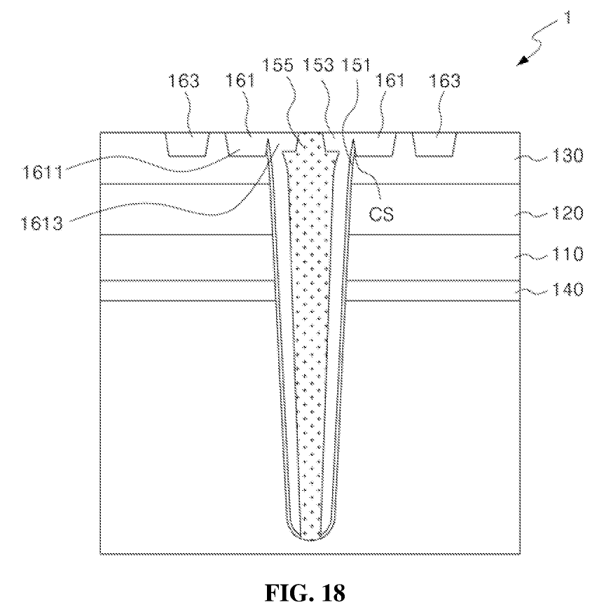

Next, referring to FIG. 18, the STI region 160 may be formed to extend to a predetermined depth from the surface of the substrate 101. As described above, the first STI region 161 may be formed to be in contact with or overlap the outer wall of the DTI region 150. In addition, the second STI region 163 may include one or more second STI regions formed at a side adjacent to the DTI region 150. At this point, since the LOCOS process for the first STI region 161 has not been performed, the lower surface of the outer region 1611 of the first STI region 161 may be located at substantially the same depth as the lower surface of the second STI region 163 within the substrate 101. In addition, the silicon penetration region CS is present between the outer region 1611 and the DTI region 150.

Next, the field oxide film 170 may be formed on the surface of the substrate 101. Hereinafter, the formation process of the field oxide film 170 will be described in detail.

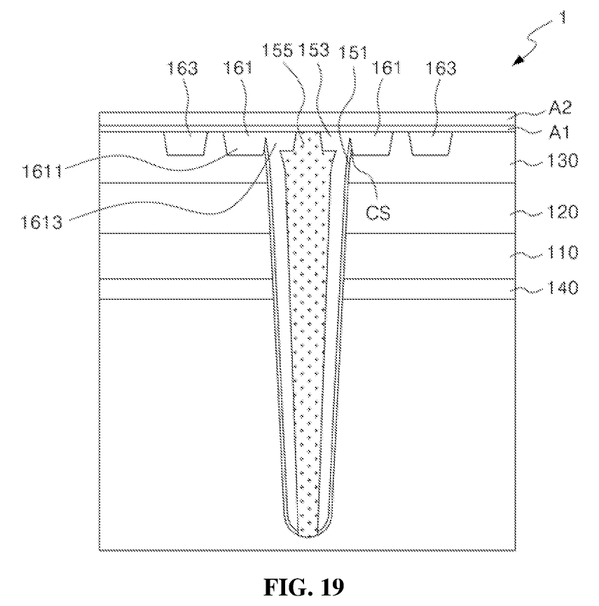

Referring to FIG. 19, a pad oxide film A1 is formed on the substrate 101, and a nitride film A2 is, for example, formed on the pad oxide film A1. The nitride film A2 may be made of Si3N4, etc.

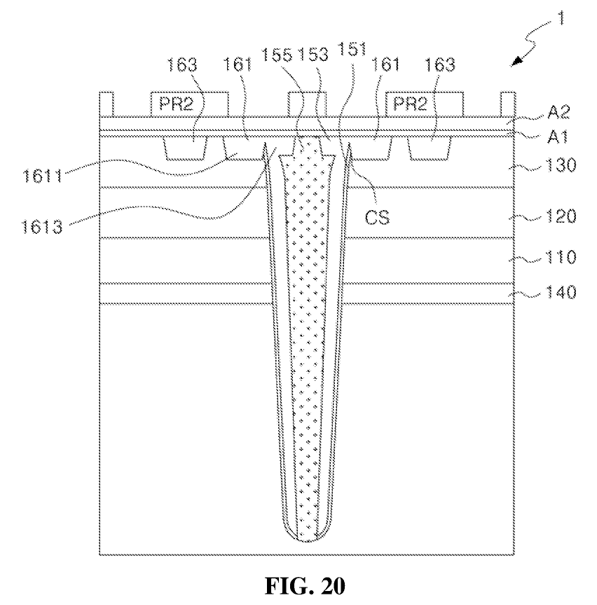

Next, referring to FIG. 20, a photoresist film PR2 on the nitride film A2 is used as a mask pattern, and the open side of the pattern is etched. That is, the nitride film A2 may be etched. In this case, sides at which the first STI region 161 and the field oxide film 170 are formed are not covered at least partially by the photoresist film PR2. In this process, by adjusting the pattern of the photoresist film PR2, it is possible to determine whether to perform the LOCOS process for the inner region 1613. In addition, the second STI region 163 is covered by the photoresist film PR2. In addition, on the first STI region 161, the pad oxide film A1 may be removed.

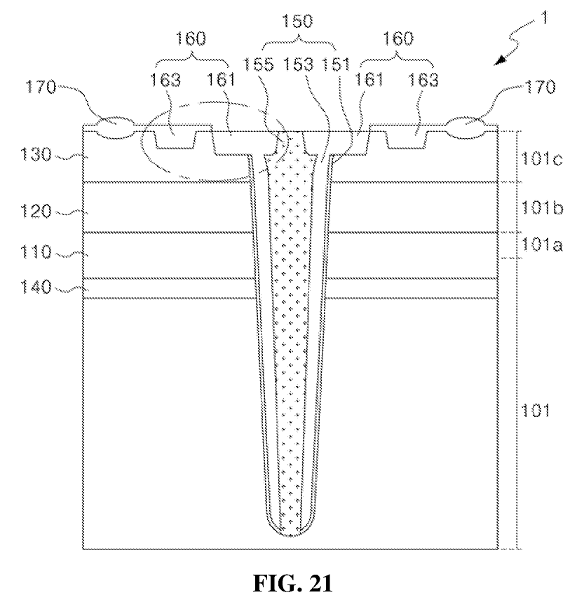

Next, referring to FIG. 21, through the thermal oxidation process, the oxide film of the first STI region 161 and the pad oxide film A1 on a side at which the field oxide film 170 is to be formed may grow. Through this process, the silicon penetration region CS may be removed or minimized by the first STI region 161. In addition, the field oxide film 170 may be formed at a fixed location. According to an embodiment of the present disclosure, by removing the silicon penetration region CS in the above-described manner, a separate additional process for removing the region CS is not required, thereby preventing a decrease in process efficiency. That is, the silicon penetration region CS may be easily removed by changing only the mask pattern.

In addition, the silicon penetration region CS is changed into an oxide film, and the vertical thickness and width of the first STI region 161 increase, so that the breakdown voltage characteristics of the device may be improved due to the increase in the size of the first STI region 161.

The detailed description above is illustrative of the present disclosure. Additionally, the foregoing describes preferred embodiments of the present disclosure, and the present disclosure may be used in various other combinations, modifications, and circumstances thereof. That is, changes or modifications may be made within the scope of the concept of the invention disclosed in this specification, a scope equivalent to the written disclosure, and/or the scope of technology or knowledge in the art. The above-described embodiments illustrate the best state for implementing the technical idea of the present disclosure, and various changes thereof required for specific application fields and uses of the present disclosure are also possible. Accordingly, the above detailed description of the invention is not intended to limit the present disclosure to the disclosed embodiments.

What is claimed is:

1. A high voltage semiconductor device isolation structure comprising:
a substrate:
a DTI region extending to a first predetermined depth from a surface of the substrate; and
an STI region extending to a second predetermined depth from the surface of the substrate,
wherein the STI region comprises:
a first STI region that is in contact with or overlaps an outer wall of the DTI region; and
a second STI region that is spaced apart from the first STI region and the DTI region.

2. The high voltage semiconductor device isolation structure of claim 1, wherein the first STI region has a size different from a size of the second STI region.

3. The high voltage semiconductor device isolation structure of claim 1, wherein the first STI region has a width larger than a width of the second STI region.

4. The high voltage semiconductor device isolation structure of claim 1, wherein the first STI region comprises an outer region having one side entirely in contact with the outer wall of the DTI region.

5. The high voltage semiconductor device isolation structure of claim 1, wherein a lower surface of an outer region of the first STI region is positioned at a side deeper within the substrate than a lower surface of the second STI region.

6. The high voltage semiconductor device isolation structure of claim 5, further comprising:
a field oxide film disposed on the surface of the substrate,
wherein the first STI region is configured to grow through a thermal oxidation during a formation of the field oxide film.

7. The high voltage semiconductor device isolation structure of claim 6, wherein the first STI region comprises an inner region that overlaps the DTI region.

8. The high voltage semiconductor device isolation structure of claim 7, wherein the inner region has a structure in which a lower surface of the inner region is convex downward.

9. A high voltage semiconductor device isolation structure comprising:
a substrate:
a DTI region extending to a first predetermined depth from a surface of the substrate;
an STI region extending to a second predetermined depth from the surface of the substrate, the STI region having a smaller vertical length compared to a vertical length of the DTI region; and
a field oxide film disposed on the surface of the substrate,
wherein the STI region comprises:
a first STI region that is in contact with or overlaps an outer wall of the DTI region; and
a second STI region that is spaced apart from the first STI region and the DTI region,
wherein the first STI region comprises:
an outer region having one side entirely in contact with the outer wall of the DTI region; and
an inner region that overlaps the DTI region.

10. The high voltage semiconductor device isolation structure of claim 9, wherein the STI region is formed after the DTI region is formed.

11. The high voltage semiconductor device isolation structure of claim 10, wherein a lower surface of the outer region of the first STI region is positioned at a side deeper within the substrate than a lower surface of the second STI region.

12. The high voltage semiconductor device isolation structure of claim 9, wherein the first STI region has a lower part connected directly to the outer wall of the DTI region adjacent thereto.

13. The high voltage semiconductor device isolation structure of claim 9, wherein the first STI region is completed by performing a LOCOS (Local Oxidation of Silicon) process.

14. The high voltage semiconductor device isolation structure of claim 13, wherein the inner region of the first STI region has a lower surface that is not substantially flat.

15. A method of manufacturing a high voltage semiconductor device isolation structure, the method comprising:
forming a deep trench by etching a substrate;
forming a DTI region within the deep trench;
forming, within the substrate, a first STI region that is in contact with or overlaps an outer wall of the DTI region, and a second STI region that is spaced apart from the DTI region and the first STI region; and
forming a field oxide film on a surface of the substrate,
wherein the first STI region is grown by a thermal oxidation process performed during the forming of the field oxide film.

16. The method of claim 15, wherein the forming of the field oxide film comprises:
forming a pad oxide film on the substrate;
forming a nitride film on the pad oxide film;
removing, partially, the nitride film by forming a photoresist film on the nitride film; and
forming the field oxide film and growing the first STI region by growing the pad oxide film by the thermal oxidation process.

17. The method of claim 15, wherein the first STI region comprises:
an outer region having one side entirely in contact with the outer wall of the DTI region;
wherein a lower surface of the outer region is located at a side deeper within the substrate than a lower surface of the second STI region.

18. The method of claim 17, wherein the outer region of the first STI region has one lateral lowest end portion in direct contact with the outer wall of the DTI region adjacent thereto.

19. The method of claim 17, wherein the first STI region further comprises:
an inner region that overlaps the DTI region,
wherein the inner region has a curved cross-sectional shape at an edge of a lower surface thereof.

20. The method of claim 15, further comprising:
forming an ion implantation region within the substrate before the forming of the DTI region; and
forming a buried layer on the ion implantation region before the forming of the DTI region.
